(19) United States
(12) Patent Application Publication
(10) Pub. No.: US 2016/0284713 A1
(43) Pub. Date: Sep. 29, 2016

(54) SEMICONDUCTOR MEMORY DEVICE

(71) Applicant: Powerchip Technology Corporation, Hsinchu (TW)

(72) Inventor: Yuji Kihara, Tokyo (JP)

(21) Appl. No.: 14/844,001

(22) Filed: Sep. 3, 2015

(30) Foreign Application Priority Data
Mar. 26, 2015 (JP) 2015-064413

(51) Int. Cl. H01L 27/11

(52) U.S. Cl. CPC H01L 27/1108

(57) ABSTRACT

The semiconductor memory device of the invention includes 2 TFT MOS transistors, 2 bulk MOS transistors, a first and second access MOS transistors and a first and second capacitor. The TFT and bulk MOS transistors form a latch for retaining a data that is inverted between a first and second node. The first bulk access MOS transistor switches the first node to connect to a first bit line according to a voltage of a word line. The second bulk access MOS transistor, switches the second node to connect to a second bit line according to the voltage of the word line. The first capacitor is disposed between the first node and a power supply voltage. The second capacitor is disposed between the second node and the power supply voltage. The bulk MOS transistors and the access MOS transistors are formed by a recess gate type MOS transistor.

### CROSS-REFERENCE TO RELATED APPLICATION

This application claims the priority benefit of Japan application serial no. 2015-064413, filed on Mar. 26, 2015. The entirety of the above-mentioned patent application is hereby incorporated by reference herein and made a part of this specification.

### BACKGROUND OF THE INVENTION

1. Field of the Invention

The invention relates to a semiconductor memory device and relates particularly to a volatile semiconductor memory device such as a static random access memory (SRAM).

2. Description of Related Art

An SRAM is a volatile semiconductor memory device; and may be defined as a volatile RAM that does not require an activation of the internal circuit for retaining memory. Typically, a flip-flop is used as a means for retaining memory and is a basic structure of RAM. Due to the introduction of dynamic random access memory (DRAM) which is RAM that requires refreshing in order for retaining memory, the modifier “static” was added for distinction. In addition to a transistor, the circuit elements used for achieving the flip-flop include a resistive element (including a variable resistive element) and a passive element such as a capacitor. However, by definition, a flip-flop action is not required, and a device for storing through circuit means including a transistor and a passive element and does not require refreshing may be considered as SRAM.

### PATENT DOCUMENTS

[Patent Document 1] Japan Laid Open Patent 2013-016581
[Patent Document 2] Japan Laid Open Patent 2013-172090
[Patent Document 3] Japan Laid Open Patent 2014-138141
[Patent Document 4] Japan Laid Open Patent 2014-175647
[Patent Document 5] PCT Publication 2011/024956
[Patent Document 6] PCT Publication 2011/108768
[Patent Document 7] Japan Laid Open Patent 2004-153037 (FIG. 44)
[Patent Document 8] Japan Laid Open Patent 2005-012109 (FIG. 12)

### NON-PATENT DOCUMENTS

[Non-Patent Document 1] Kihara Yuji et al, “New SRAM using DRAM technology”, Electronic Communication Society Magazine Article, C, Electronics, J89-C (10), pp. 725-734, 2006 Oct. 1
[Non-Patent Document 2] Kihara Yuji et al, “Super SRAM technology for soft error countermeasure”, Electronic Communication Society Magazine Article, C, Electronics, J90-C (4), pp. 378-389, 2007 Apr. 1
[Non-Patent Document 3] M. Yamaoka et al., “SRAM Circuit With Expanded Operating Margin and Reduced Stand-By Leakage Using Thin-Box FD-SOI Transistors,” IEEE Journal of Solid-state Circuits, Vol. 41, No. 11, pp. 2366-2372, November 2006
[Non-Patent Document 4] M. Yamada et al., “Soft Error Improvement of Dynamic RAM with Hi-C structure”, Technical Digest of International Electron Devices Meeting 1980, pp. 578-581, 1980

FIG. 1 is a circuit diagram illustrating 3 types of prior art construction examples relating to a memory cell of an SRAM. As shown in FIG. 1, an SRAM may be classified as a CMOS type SRAM as shown in FIG. 1(a), a TFT load type SRAM as shown in FIG. 1(b) and a high resistance type SRAM as shown in FIG. 1(c) (for example, refer to Patent Documents 1˜4, non-Patent Documents 1˜2). Description is provided below.

(1) CMOS Type SRAM (FIG. 1(a))

An SRAM using a CMOS type memory cell includes 4 MOS transistors Q101˜Q104 forming a latch for retaining 1 bit of data that is inverted between the nodes P1, P2, and 2 access MOS transistors Q105, Q106, in which all are located between bit lines BL, BL′ and a word line WL. It is a memory device which uses the CMOS process most effectively. A special construction of the memory cell is not required since the memory cell is formed by the same CMOS as the peripheral circuit and also has excellent characteristics. Thus, it is an old technology that has been used since a time when the CMOS process was introduced. However, the bulk transistors included are 2 P-channel transistors and 4 N-channel transistors for a total number of 6 and a problem where separation of the 2 types of transistors is required which leads to a large memory cell size and increased cost. The advantages in the characteristics of the CMOS type memory cell are the low activation voltage characteristics and low stand-by current characteristics.

(2) High Resistance Load Type SRAM (FIG. 1(c))

In a high resistance load type SRAM, the load is formed by a high resistance element HR1, HR2 and the high resistance is constituted by a poly-silicon with a suppressed impurity concentration. The numbers of bulk transistors included are 4 N-channel transistors and therefore a separation region is not required. As such, the memory cell may be made smaller and the cost may be reduced. However, in order to achieve stable flip-flop characteristics, the dimension of the N-channel transistor used as an inverter is required to be set approximately 3 times larger than the N-channel transistor used as an access gate. Depending on the structure, in actuality the area difference compared to the CMOS SRAM is about 20 percent.

TFT Load Type SRAM (FIG. 1(b))

The TFT load type SRAM uses the TFT type MOS transistors Q101T, Q102T which achieve transistor action by a poly-silicon called TFT (Thin Film Transistor) as a load, and was developed for suppressing the stand-by current with respect to the high resistance. Because the transistor is formed by poly-silicon, the on/off ratio is not comparable to the bulk transistor. However, the stand-by current may be suppressed to an extent comparable to the CMOS type through arranging with high resistance poly-silicon technologies.

In a single unit LP (low power) SRAM, the 3 types of memory cells mentioned above have been used along with changes in technology. The characteristics which were advantageous to the CMOS type SRAM were its low activation voltage characteristic and low stand-by current characteristic. However, this advantage was not able to be demonstrated during a time when power voltages were high. Since memory cells other than the CMOS type SRAM would also work sufficiently for power voltages of 5V or 3V, there was not a problem. The stand-by current characteristics of the CMOS type SRAM was superior compared to the high resistance load type, but by increasing the resistance value of the high resistance, decent suppression was possible. Therefore, the two co-existed in a balance between price and characteristics. Due to the issue of price in the market, the high resistance load type had an advantage. This situation continued for a while, however along with the advances in miniaturization, low voltage applications correspondingly advanced and a change was brought to SRAM technology. In low voltages below 1.8 V, the high resistance load type and the TFT load type SRAM's in which action characteristics are determined solely by the N-channel transistors, the low voltage actions are difficult. In this way, the CMOS type in which the low voltage action characteristics are superior prevailed as the memory cell. Currently, there are TFT load type SRAMs manufactured in a small capacity in single unit SRAMs.

From a standpoint that a high speed SRAM is basically a type of memory cell, it is similar to the LPSRAM, however the perspective for determining the memory cell differs slightly. From the perspective of high speediness, the high resistance load type SRAM with a smaller memory size has an advantage. The reason being, the wiring length in the memory cell array and the peripheral parts may be reduced. In addition, because a low stand-by current was not often required, therefore the characteristics of the CMOS SRAM could not be demonstrated. In this way, at one time it was typical to adopt the high resistance load type SRAM in a high speed SRAM. However, low voltage action characteristics similarly became important for the high speed SRAM. This was due to using the leading miniaturization technology for the high speediness and lowered action current. In order for miniaturization, the power voltage applied to a memory cell needs to be suppressed. Therefore, the CMOS type SRAM superior in low voltage action has been adopted. In a built-in SRAM, the CMOS type SRAM is used throughout because it is a principle to adopt the CMOS used in a logic circuit as it is.

In this way, the issues relating to an SRAM of conventional art is as follows.

(1) Memory cell size is relatively large, memory cost also increases.
(2) Soft errors and latch up occur from radiation.
(3) Stand-by current is relatively large.
(4) Lower low voltage action is desirable.

An objective of the invention is to provide a volatile semiconductor memory device to solve the above issues, making the memory size smaller and memory cost lower, preventing soft errors and latch ups, lowering the stand-by current and achieving a lower low voltage action compared to conventional art.

### SUMMARY OF THE INVENTION

The semiconductor memory device, which is capacitor memory type, of the first invention includes 2 TFT type P-channel MOS transistors and 2 bulk N-channel MOS transistors forming a latch for retaining a data that is inverted between a first node and a second node; a first bulk access MOS transistor, switching the first node to connect to a first bit line or not according to a voltage of a word line; a second bulk access MOS transistor, switching the second node to connect to a second bit line or not according to the voltage of the word line; a first capacitor, disposed between the first node and a particular power supply voltage; and a second capacitor, disposed between the second node and the power supply voltage, wherein the 2 bulk N-channel MOS transistors, the first access MOS transistor and the second access MOS transistor are formed by a recess gate type MOS transistor.

The semiconductor memory device, which is capacitor memory type, of the second invention includes 2 TFT type P-channel MOS transistors and 2 TFT type N-channel MOS transistors forming a latch for retaining a data that is inverted between a first node and a second node; a first bulk access MOS transistor, switching the first node to connect to a first bit line or not according to a voltage of a word line; a second bulk access MOS transistor, switching the second node to connect to a second bit line or not according to the voltage of the word line; a first capacitor, disposed between the first node and a particular power supply voltage; and a second capacitor, disposed between the second node and the power supply voltage, wherein the 4 TFT type MOS transistors are a vertical type TFT type MOS transistor respectively, and include a first P-channel MOS transistor, a second P-channel MOS transistor, a first N-channel MOS transistor and a second N-channel MOS transistor, in which the first P-channel MOS transistor and the first N-channel MOS transistor have a same gate and form a first inverter, and the second P-channel MOS transistor and the second N-channel MOS transistor have a same gate and form a second inverter.

The semiconductor memory device, which is capacitor memory type, of the third invention includes 2 TFT type P-channel MOS transistors for retaining a data that is inverted between a first node and a second node; a first bulk access MOS transistor, switching the first node to connect to a first bit line or not according to a voltage of a word line; a second bulk access MOS transistor, switching the second node to connect to a second bit line or not according to the voltage of the word line; a first capacitor, disposed between the first node and a particular power supply voltage; and a second capacitor, disposed between the second node and the power supply voltage, wherein the first access MOS transistor and the second access MOS transistor have a leak function, in which the first access MOS transistor is controlled by the leak function according to a voltage of the second node and the second access MOS transistor is controlled by the leak function according to a voltage of the first node.

In an embodiment of the invention, the first access MOS transistor and the second access MOS transistor have an SOI structure and have a back gate control terminal respectively and further includes a third capacitor, disposed between the second node and the back gate control terminal of the first access MOS transistor; and a fourth capacitor, disposed between the first node and the back gate control terminal of the second access MOS transistor.

In an embodiment of the invention, the first access MOS transistor and the second access MOS transistor have a metal-oxide-nitride-oxide-semiconductor structure or a particular gate structure; the first access MOS transistor and the second access MOS transistor have a sub-gate respectively; the second node is connected to the sub-gate of the first access MOS transistor; and the first node is connected to the sub-gate of the second access MOS transistor.

In an embodiment of the invention, the first capacitor and the second capacitor are formed by sandwiching a hafnium oxide film or a zirconium oxide film between a pair of metal films.

The semiconductor memory device, which is capacitor memory type, of the fourth invention includes a first second TFT type P-channel MOS transistor and a second TFT type P-channel MOS transistor for retaining a data that is inverted between a first node and a second node; a first bulk access MOS transistor, switching the first node to connect to a first bit line or not according to a voltage of a word line; a second bulk access MOS transistor, switching the second node to connect to a second bit line or not according to the voltage of the word line, wherein the first TFT type P-channel MOS transistor includes a first capacitor integrally formed, disposed between the first node and a particular power supply voltage and the second TFT type P-channel MOS transistor includes a second capacitor integrally formed, disposed between the second node and the power supply voltage.

In an embodiment of the invention, the first access MOS transistor and second access MOS transistor have a leak function, the first access MOS transistor is controlled by the leak function according to a voltage of the second node and the second access MOS transistor is controlled by the leak function according to a voltage of the first node.

In an embodiment of the invention, the first access MOS transistor and the second access MOS transistor have an SOI structure and have a back gate control terminal respectively, and further include a third capacitor, disposed between the second node and the back gate control terminal of the first access MOS transistor; and a fourth capacitor, disposed between the first node and the back gate control terminal of the second access MOS transistor.

In an embodiment of the invention, the first access MOS transistor and the second access MOS transistor have a metal-oxide-nitride-oxide-semiconductor structure or a particular gate structure; the first access MOS transistor and the second access MOS transistor have a sub-gate respectively; the second node is connected to the sub-gate of the first access MOS transistor; and the first node is connected to the sub-gate of the second access MOS transistor.

The invention provides a semiconductor memory device having smaller memory size and lower memory cost, and prevents soft errors and latch ups, lowers the stand-by current and achieves a lower low voltage action compared to conventional art.

### BRIEF DESCRIPTION OF THE DRAWINGS

FIG. 1(a)-FIG. 1(c) are a circuit diagram illustrating 3 types of prior art construction examples relating to a memory cell of an SRAM.

FIG. 2 is a circuit diagram illustrating a construction example of a storage capacitor type SRAM relating to an embodiment 1 of the invention.

FIG. 3 is a longitudinal sectional-view illustrating a construction of a part of the storage capacitor type SRAM of FIG. 2.

FIG. 4 is a circuit diagram illustrating a construction example of a storage capacitor type SRAM relating to an embodiment 2 of the invention.

FIG. 5 is a longitudinal sectional-view illustrating a part of a construction of the storage capacitor type SRAM of FIG. 4.

FIG. 6 is a circuit diagram illustrating a construction example of a storage capacitor type SRAM relating to an embodiment 3 of the invention.

FIG. 7 is a longitudinal sectional-view illustrating a construction of SOI (silicon on insulator) type access MOS transistors Q5L, Q6L used in the storage capacitor type SRAM of FIG. 6.

FIG. 8 is a circuit diagram illustrating a construction example of a storage capacitor type SRAM relating to an embodiment 4 of the invention.

FIG. 9A is a longitudinal sectional-view along the line A-A′ of FIG. 9B illustrating a construction example 1 of an access MOS transistor Q5M, Q6M used in the storage capacitor type SRAM of FIG. 8.

FIG. 9B is a top view of the access MOS transistors Q5M, Q6M of FIG. 9A.

FIG. 10A is a longitudinal sectional-view along the line B-B′ of FIG. 10B illustrating a construction example 2 of an access MOS transistor Q5M, Q6M used in the storage capacitor type SRAM of FIG. 8.

FIG. 10B is a top view of the access MOS transistors Q5M, Q6M of FIG. 10A.

FIG. 11A is a longitudinal sectional-view along the line C-C′ of FIG. 11B illustrating a construction example 3 of an access MOS transistor Q5M, Q6M used in the storage capacitor type SRAM of FIG. 8.

FIG. 11B is a top view of the access MOS transistors Q5M, Q6M of FIG. 11A.

FIG. 12A is a longitudinal sectional-view along the line D-D′ of FIG. 10B illustrating a construction example 4 of an access MOS transistor Q5M, Q6M used in the storage capacitor type SRAM of FIG. 8.

FIG. 12B is a top view of the access MOS transistors Q5M, Q6M of FIG. 12A.

FIG. 13 is a circuit diagram illustrating a construction example of a storage capacitor type SRAM relating to an embodiment 5 of the invention.

FIG. 14 is a longitudinal sectional-view illustrating a construction example 1 of a TFT type MOS transistor Q1C, Q2C having a large capacity capacitor adapted for the storage capacitor type SRAM of FIG. 13.

FIG. 15A is a longitudinal sectional-view illustrating a construction example 2 of a TFT type MOS transistor Q1C, Q2C having a large capacity capacitor adapted for the storage capacitor type SRAM of FIG. 13.

FIG. 15B is a longitudinal sectional-view illustrating a basic construction of the TFT type MOS transistors Q1C, Q2C having a large capacitance capacitor of FIG. 15A.

FIG. 16 is a longitudinal sectional-view illustrating a construction example 1 of a part of the storage capacitor type SRAM of FIG. 13.

FIG. 17 is a longitudinal sectional-view illustrating a construction example 2 of a part of the storage capacitor type SRAM of FIG. 13.

FIG. 18 is a circuit diagram illustrating a construction example of a storage capacitor type SRAM relating to an embodiment 6 of the invention.

FIG. 19 is a circuit diagram illustrating a construction example of a storage capacitor type SRAM relating to an embodiment 7 of the invention.

FIG. 20 is a circuit diagram illustrating a construction example of a storage capacitor type SRAM relating to an embodiment 8 of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### Embodiment 1

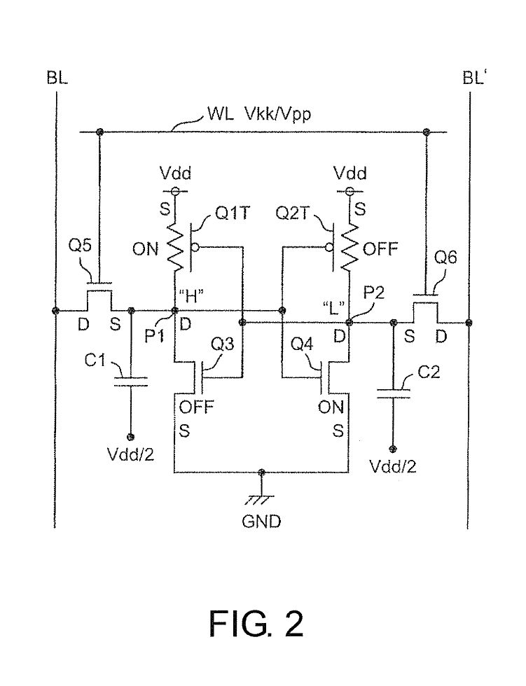

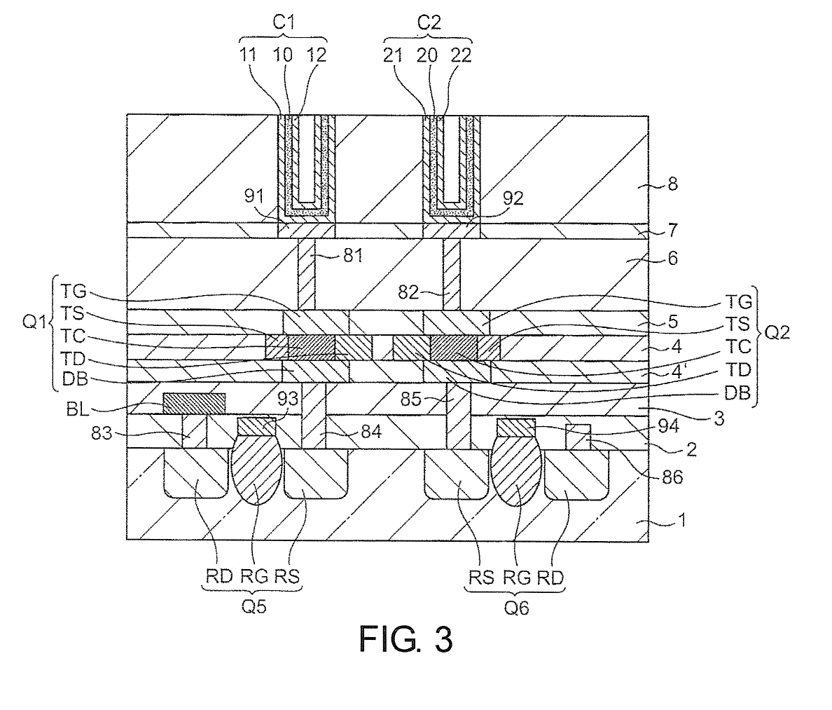

FIG. 2 is a circuit diagram illustrating a construction example of a storage capacitor type SRAM relating to an embodiment 1 of the invention. FIG. 3 is a longitudinal sectional-view illustrating a construction of a part of the storage capacitor type SRAM of FIG. 2.

Referring to FIG. 2, a storage capacitor type SRAM relating to embodiment 1 includes 4 MOS transistors Q1T, Q2T, Q3, Q4 forming a latch and 2 N-channel access MOS transistors Q5, Q6, all located between bit lines BL, BL′ and a word line WL. Here, the MOS transistors Q1T, Q2T are TFT type P-channel MOS transistors and the other 4 MOS transistors Q3˜Q6 are recess gate type N-channel bulk transistors (for example, refer to Patent Document 1). In the semiconductor layer structure of the MOS transistors, the current storage capacitor type SRAM is characterized in that the recess gate is constituted by forming a recess for receiving a gate electrode and then forming a gate electrode inside therein.

In addition, referring to FIG. 3, a capacitor C1, for example, is formed by sandwiching an insulating film 10 constituted from hafnium oxide (or zirconium oxide) between the electrode films 11, 12. A capacitor C2, for example, is formed by sandwiching an insulating film 20 constituted from hafnium oxide (or zirconium oxide) between the electrode films 21, 22.

In FIG. 2, the bit line BL is connected to a node P1 through a source and drain of the access MOS transistor Q5. In addition, the bit line BL′ is connected to a node P2 through a source and drain of the access MOS transistor Q6. Furthermore, the word line WL is connected to each gate of the access MOS transistors Q5, Q6. The node P1 is connected to a power voltage Vdd/2 through the capacitor C1, and is connected to each drain of the MOS transistors Q1T, Q3 and each gate of the MOS transistors Q2T, Q4. The node P2 is connected to a power voltage Vdd/2 through the capacitor C2, and is connected to each drain of the MOS transistor Q2T, Q4 and each gate of the MOS transistor Q1T, Q3. Each source of the MOS transistors Q1T, Q2T is connected with the power voltage Vdd and each source of the MOS transistors Q3, Q4 is connected to ground.

In the storage capacitor type SRAM constructed above, the MOS transistors Q1T, Q3 form a first inverter and the MOS transistors Q2T, Q4 form a second inverter. The latch for retaining 1 bit of data that is inverted between the nodes P1, P2 is formed by connecting the first inverter and the second inverter in parallel in an opposite direction to each other in a loop shape. Here, for example, when the MOS transistors Q1T, Q4 are on and the MOS transistors Q2T, Q3 are off, a high level voltage is induced at the node P1 and is stored and retained by the capacitor C1, and a low level voltage is induced at the node P2. The access MOS transistor Q5 selectively switches between connecting the node P1 to the bit line BL or not according to the voltage of the word line WL. In addition, the access MOS transistor Q6 selectively switches between connecting the node P2 to the bit line BL′ or not according to the voltage of the word line WL.

The bit line BL is precharged by the power voltage Vdd, and is driven by the capacitor C1 and the MOS transistors Q1T, Q3 or by the capacitor C2 and the MOS transistors Q2T, Q4 and varies between 0˜Vdd (for example 1V). The word line WL is driven by the high voltage Vpp and changes between Vkk (for example −0.5V) ˜Vpp (for example 2V). In this way, operation at high speed under a low power supply voltage may be achieved.

In FIG. 3, the storage capacitor type SRAM of FIG. 2 is formed on a plurality of insulation films 2˜8 laminated on a semiconductor substrate 1. The access MOS transistors Q5, Q6 are formed by a drain region RD, a recess type gate region RG and a source region RS in the semiconductor substrate 1 respectively. The drain region RD of the MOS transistor Q5 is connected to the bit line BL through a conductive via 83. The drain region RD of the MOS transistor Q6 is connected to the bit line BL′ through a conductive via 86. In addition, the recess type gate region RG of the MOS transistor Q5 is connected to a conductive contact 93 that forms the gate electrode. The recess type gate region RG of the MOS transistor Q6 is connected to a conductive contact 94 that forms the gate electrode. Furthermore, the source region RS of the MOS transistor Q5 is connected with a conductive contact DB of the MOS transistor Q1 through the conductive via 84. The source region RS of the MOS transistor Q6 is connected with a conductive contact DB of the MOS transistor Q2 through the conductive via 85.

The MOS transistor Q1, includes the conductive contact DB formed in the layer of the insulation film 4′, a source region TS, a TFT type P-channel region TC and a drain region TD formed juxtaposed in the layer of the insulation film 4 and a gate region TG formed in the layer of the insulation film 5, so as to form a vertical type TFT type MOS transistor Q1. The gate region TG of the MOS transistor Q1 is connected to the conductive contact 91 through the conductive via 81 formed in the layer of the insulation film 6 and the conductive contact 91 is connected with the electrode film 11 of the capacitor C1. In addition, the MOS transistor Q2, includes the conductive contact DB formed in the layer of the insulation film 4′, a source region TS, a TFT type P-channel region TC and a drain region TD formed juxtaposed in the layer of the insulation film 4 and a gate region TG formed in the layer of the insulation film 5, so as to form a vertical type TFT type MOS transistor Q2. The gate region TG of the MOS transistor Q2 is connected to the conductive contact 92 through the conductive via 82 formed in the layer of the insulation film 6 and the conductive contact 92 is connected with the electrode film 21 of the capacitor C2.

The MOS transistors Q1, Q2 in FIG. 2 are formed by the vertical type TFT type MOS transistors, however it should not be construed as a limitation to the invention. The gate region TG, the source region TS and the drain region TD may be formed juxtaposed in the horizontal direction so as to form a normal horizontal type TFT type P-channel MOS transistor.

The storage capacitor type SRAM related to embodiment 1 constructed above, includes the 2 TFT type P-channel MOS transistors Q1T, Q2T, the 4 recess gate type MOS transistors Q3˜Q6 and the 2 capacitors C1, C2, such that the storage capacitor type SRAM may be formed using an advanced process, and compared to conventional art, operation at high speed under a low power supply voltage may be achieved.

### Embodiment 2

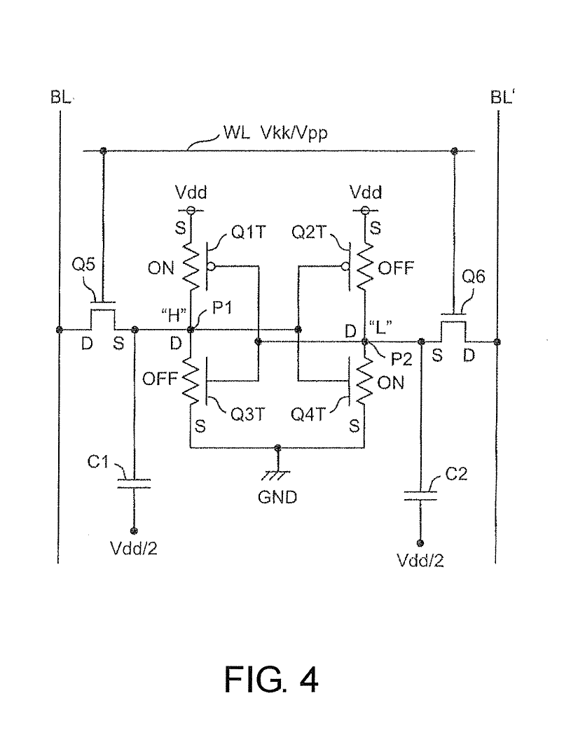

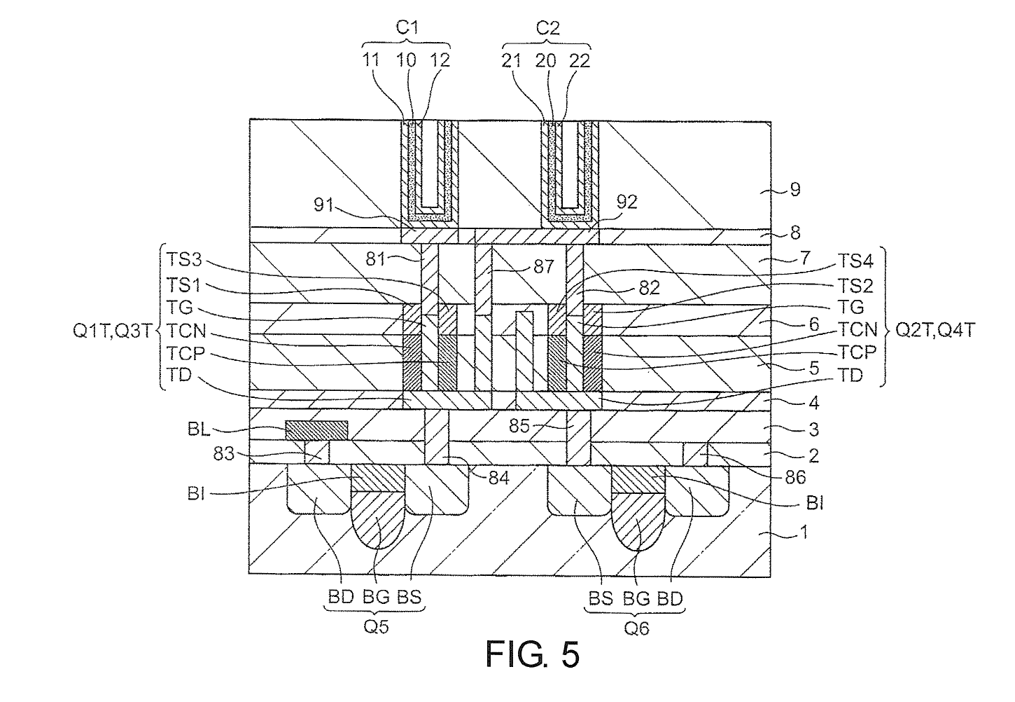

FIG. 4 is a circuit diagram illustrating a construction example of a storage capacitor type SRAM relating to an embodiment 2 of the invention. FIG. 5 is a longitudinal sectional-view illustrating a part of a construction of the storage capacitor type SRAM of FIG. 4.

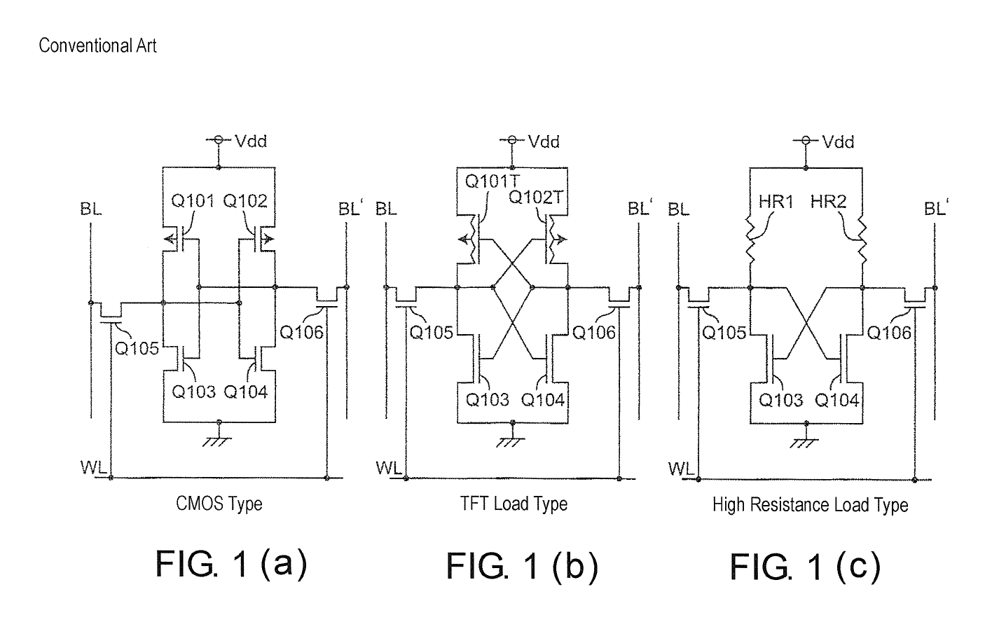

Comparing the storage capacitor type SRAM relating to embodiment 2 in FIG. 4 with the storage capacitor type SRAM relating to embodiment 1 in FIG. 1, the differences are as described below.

(1) The TFT type N-channel MOS transistors Q3T, Q4T are included in place of the bulk MOS transistors Q3, Q4 respectively.

(2) The TFT type MOS transistors Q1T, Q3T are formed by the vertical type integrated TFT type MOS transistors Q1T, Q3T having the same gate region TG of FIG. 5.

(3) The TFT type MOS transistors Q2T, Q4T are formed by the vertical type integrated TFT type MOS transistors Q2T, Q4T having the same gate region TG of FIG. 5.

In FIG. 5, the MOS transistors Q1T, Q3T form a first inverter and the MOS transistors Q2T, Q4T form a second inverter. The access MOS transistors Q5, Q6 include a drain region BD, a buried type gate region BG and a source region BS formed juxtaposed respectively at the semiconductor substrate 1, so as to form an buried gate type MOS transistor (for example, refer to Patent Document 6). In addition, an insulation film BI for burying is formed on each gate region BG. The source region BS of the MOS transistor Q5 is connected to the conductive contact TD of the MOS transistors Q1T, Q3T through the conductive via 84 formed at the insulation layers 2, 3. Furthermore, the source region BS of the MOS transistor Q6 is connected to the conductive contact TD of the MOS transistors Q2T, Q4T through the conductive via 85 formed at the insulation layers 2, 3.

The MOS transistors Q1T, Q3T includes

(1) the N-channel region TCN, the gate region TG and the P-channel region TCP formed juxtaposed in the layer of the insulation film 5,
(2) the source region TS1 of the MOS transistor Q1T, the same gate region TG of the MOS transistors Q1T, Q3T and the source region TS3 of the MOS transistor Q3T are formed juxtaposed in the layer of the insulation film 6, so as to form a vertical type integrated TFT type MOS transistor Q1T, Q3T having 1 same gate region TG. Here, the MOS transistor Q1T is a P-channel MOS transistor and the MOS transistor Q3T is an N-channel MOS transistor.

The MOS transistor Q2T, Q4T includes

(1) the N-channel region TCN, the gate region TG and the P-channel region TCP formed juxtaposed in the layer of the insulation film 5,
(2) the source region TS1 of the MOS transistor Q2T, the same gate region TG of the MOS transistors Q2T, Q4T and the source region TS3 of the MOS transistor Q4T are formed juxtaposed in the layer of the insulation film 6, so as to form a vertical type integrated TFT type MOS transistors Q2T, Q4T having 1 same gate region TG. Here, the MOS transistor Q2T is a P-channel MOS transistor and the MOS transistor Q4T is an N-channel MOS transistor.

Furthermore, the gate region TG of the MOS transistors Q1T, Q3T are connected to the electrode film 11 of the capacitor C1 through the conductive via 81. The gate region TG of the MOS transistors Q1T, Q3T are connected to the gate region of the MOS transistors Q2T, Q4T and the electrode film 21 of the capacitor C2 through the conductive contact DB thereof, the conductive via 87 and the conductive contact 92.

Furthermore, in FIG. 5, similar to embodiment 1, the capacitor C1, for example, is formed by sandwiching the insulating film 10 constituted from hafnium oxide (or zirconium oxide) between the electrode films 11, 12. Similar to embodiment 1, the capacitor C2, for example, is formed by sandwiching an insulating film 20 constituted from hafnium oxide (or zirconium oxide) between the electrode films 21, 22.

In the storage capacitor type SRAM related to the embodiment 2 constructed above, each pair has the same gate region TG, and includes the 2 pairs of the vertical type integrated TFT type MOS transistors (Q1T, Q3T; Q2T, Q4T), the 2 buried gate type access MOS transistors Q5, Q6 and the 2 capacitors C1, C2, such that compared to conventional art, a storage capacitor type SRAM having high data retaining ability and a significantly smaller memory size may be achieved.

### Embodiment 3

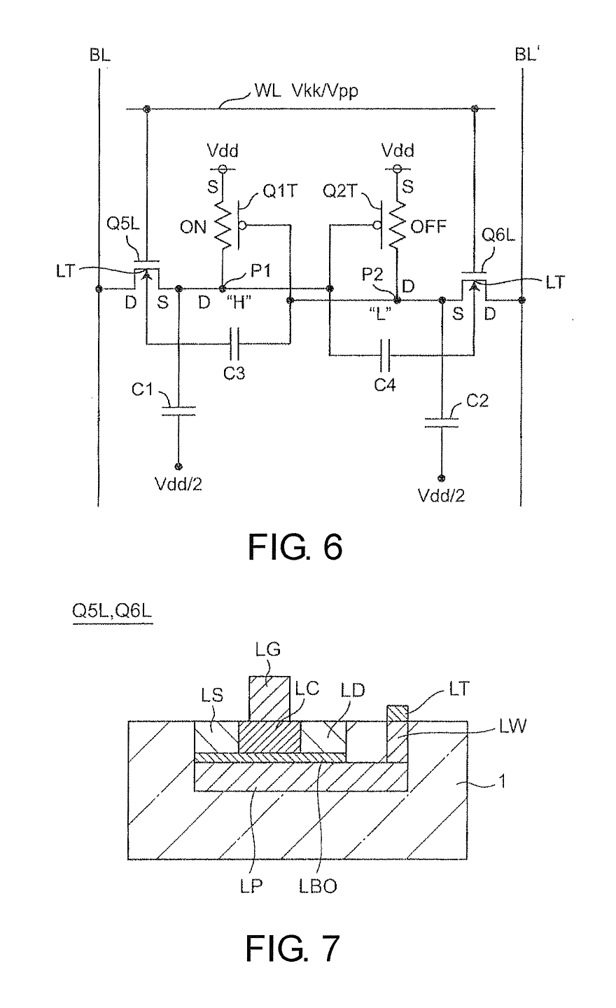

FIG. 6 is a circuit diagram illustrating a construction example of a storage capacitor type SRAM relating to an embodiment 3 of the invention. FIG. 7 is a longitudinal sectional-view illustrating a construction of SOI (silicon on insulator) type access MOS transistors Q5L, Q6L used in the storage capacitor type SRAM of FIG. 6.

Comparing the storage capacitor type SRAM relating to embodiment 3 in FIG. 6 with the storage capacitor type SRAM relating to embodiment 1 in FIG. 2, the differences are as described below.

(1) A bulk leak type MOS transistor Q5L having a back gate control terminal LT is included in place of the access MOS transistor Q5.

(2) A capacitor C3 is included in place of the MOS transistor Q3, wherein an end of the capacitor C3 is connected to the node P2 and another end of the capacitor C3 is connected to the back gate control terminal LT of the leak type MOS transistor Q5L.

(3) A bulk leak type MOS transistor Q6L having a back gate control terminal LT is included in place of the access MOS transistor Q6.

(4) A capacitor C4 is included in place of the MOS transistor Q4, wherein an end of the capacitor C4 is connected to the node P1 and another end of the capacitor C4 is connected to the back gate control terminal LT of the leak type MOS transistor Q6L.

In FIG. 7, the leak type MOS transistor Q5L, Q6L includes

(1) the source region LS, the channel region LC and the drain region LD formed juxtaposed at the semiconductor substrate 1,
(2) the gate LG formed on the channel region LC,
so as to form an SOI (Silicon On Insulator) type MOS transistor having an STI (Shallow Trench Isolation) structure (for example, refer to non-Patent Document 3). Here, a P+ impurity region LP is formed at the lower side in the semiconductor substrate 1 of the source region LS, the channel region LC and the drain region LD through a thin buried oxide layer LBO. The P+ impurity region LP is connected to the back gate control terminal LT through a well contact LW.

Here, the SOI is a technique which enhances the high speed characteristics and the low power consumption of the CMOS LSI. MOSFETS on a conventional integrated circuit form a separation between the elements using a reverse bias of a PN junction, however stray capacitance is generated between the parasitic diode and the substrate such that delayed signals and current leaks to the substrate were occurring. In order to reduce the stray capacitance, an insulation layer may be formed below the channel of the MOSFET, so as to decrease the stray capacitance. Furthermore, STI is a method for separating elements, in which a groove is formed on the Si surface by anisotropic etching, and an insulation film such as an oxide layer is buried therein, and then a planarization is performed to separate the elements. The STI has an effect of being able to narrow the element separating region because the side surface of the groove may be steepened.

Furthermore, similar to embodiment 1, the TFT type MOS transistors Q1T, Q2T may be formed as the vertical type TFT type MOS transistors or may be formed as normal horizontal type TFT type MOS transistors.

In the storage capacitor type SRAM related to the embodiment 3 constructed above, for example, when the MOS transistor Q1T is on and the MOS transistor Q2T is off, the high level voltage of the node P1 may be applied to the back gate control terminal LT of the access MOS transistor Q6L having the SOI structure through the capacitor C4, and the low level voltage of the node P2 may be applied to the back gate control terminal LT of the access MOS transistor Q5L having the SOI structure through the capacitor C3 and by retaining the bit line BL at the ground voltage during stand-by, compared to conventional art, a storage capacitor type SRAM having high data retaining ability and a significantly smaller memory size may be achieved.

### Embodiment 4

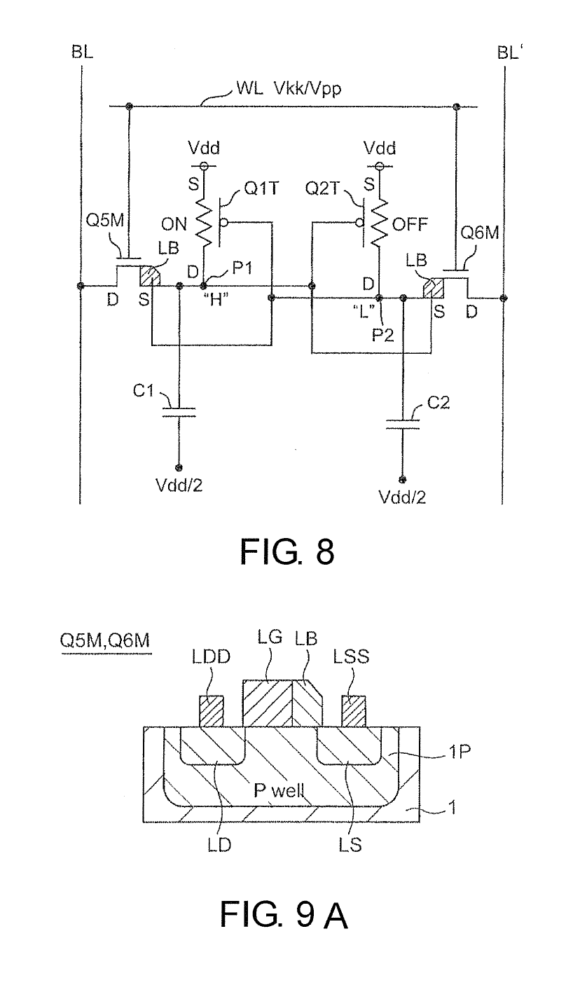

FIG. 8 is a circuit diagram illustrating a construction example of a storage capacitor type SRAM relating to an embodiment 4 of the invention. Comparing the storage capacitor type SRAM relating to embodiment 4 in FIG. 8 with the storage capacitor type SRAM relating to embodiment 1 in FIG. 2, the differences are as described below.

(1) A bulk leak type MOS transistor Q5M having a sub-gate LB is included in place of the access MOS transistor Q5.

(2) The node P2 is connected to the sub-gate LB of the leak type MOS transistor Q5M in place of the MOS transistor Q3.

(3) A bulk leak type MOS transistor Q6M having a sub-gate LB is included in place of the access MOS transistor Q6.

(4) The node P1 is connected to the sub-gate LB of the leak type MOS transistor Q6M in place of the MOS transistor Q4.

Furthermore, similar to embodiment 1, the TFT type MOS transistors Q1T, Q2T may be formed as vertical type TFT type MOS transistors or formed as normal horizontal type TFT type MOS transistors. In addition, in FIG. 8, a capacitor C1, for example, is formed by sandwiching an insulating film 10 constituted from hafnium oxide (or zirconium oxide) between the electrode films 11, 12. A capacitor C2, for example, is formed by sandwiching an insulating film 20 constituted from hafnium oxide (or zirconium oxide) between metal films 21, 22.

A variety of construction examples of the access MOS transistors Q5M, Q6M of FIG. 8 will be described below.

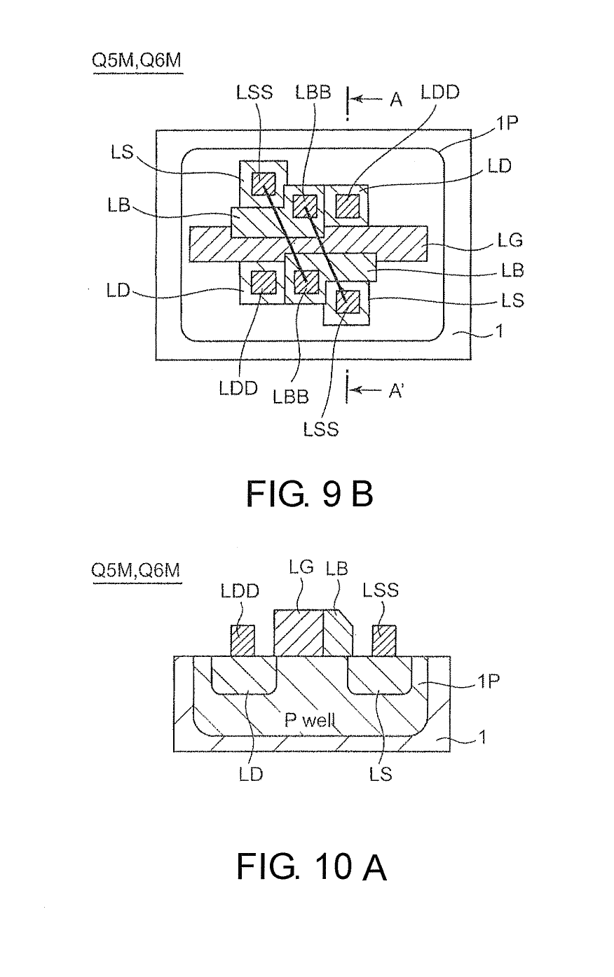

FIG. 9A is a longitudinal sectional-view along the line A-A′ of FIG. 9B illustrating a construction example 1 of an access MOS transistor Q5M, Q6M used in the storage capacitor type SRAM of FIG. 8. FIG. 9B is a top view of the access MOS transistors Q5M, Q6M of FIG. 9A. Referring to FIG. 9A and FIG. 9B, in the access MOS transistors Q5M, Q6M, an N+ drain region LD and an N+ source region LS are formed directly below the gate LG and sandwiching the channel region LC therebetween in a p-well region 1P formed in the semiconductor substrate 1 respectively. A drain LDD is formed on the N+ drain region LD and is connected to the bit line BL and a source LSS is formed on the N+ source region LS. Furthermore, the sub-gate LB is formed at the drain side of the side surface of the gate LG, so as to include and extend beyond the source region LS, to form a leak type MOS transistor Q5M, Q6M having a special gate structure (for example, refer to Patent Document 7), a so-called F-MONOS (Metal-Oxide-Nitride-Oxide-Semiconductor) structure. In addition, in FIG. 9B and thereafter, the LBB is a conductive contact of the sub-gate LB.

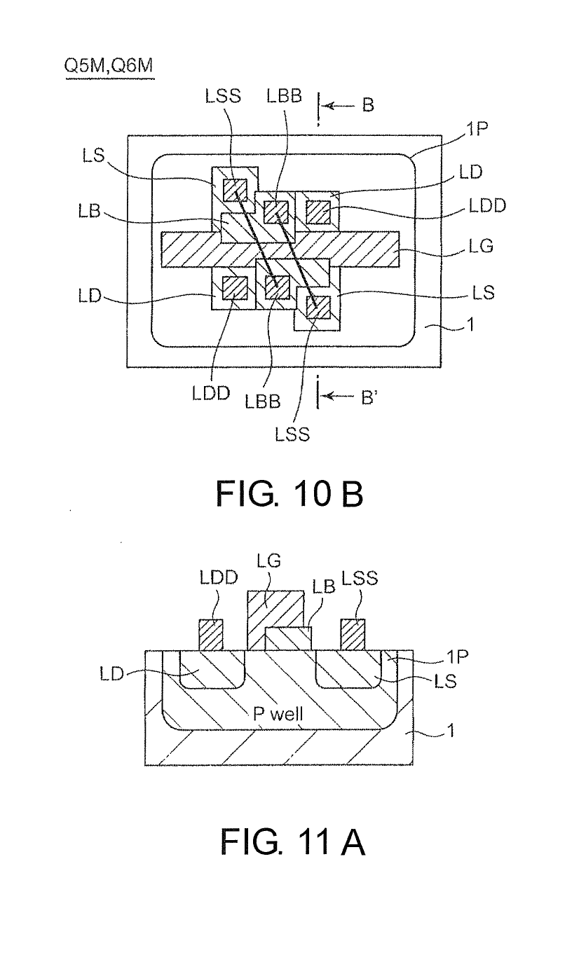

FIG. 10A is a longitudinal sectional-view along the line B-B′ of FIG. 10B illustrating a construction example 2 of an access MOS transistor Q5M, Q6M used in the storage capacitor type SRAM of FIG. 8. FIG. 10B is a top view of the access MOS transistors Q5M, Q6M of FIG. 10A. Comparing the access MOS transistors Q5M, Q6M in FIG. 10A and FIG. 10B with the access MOS transistors Q5M, Q6M in FIG. 9A and FIG. 9B, the sub-gate LB is formed at the drain side of the side surface of the gate LG, so as to include but does not extend beyond the source region LS, to form a leak type MOS transistor Q5M, Q6M having a special gate structure (for example, refer to Patent Document 7), a so-called F-MONOS structure. Other features are the same as FIG. 9A and FIG. 9B.

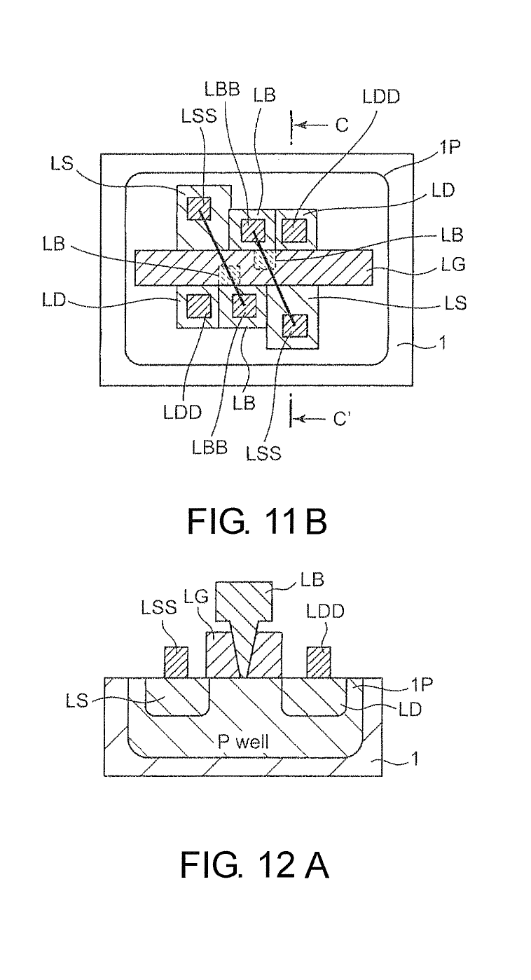

FIG. 11A is a longitudinal sectional-view along the line C-C′ of FIG. 11B illustrating a construction example 3 of an access MOS transistor Q5M, Q6M used in the storage capacitor type SRAM of FIG. 8. FIG. 11B is a top view of the access MOS transistors Q5M, Q6M of FIG. 11A. Comparing the access MOS transistors Q5M, Q6M in FIG. 11A and FIG. 11B with the access MOS transistors Q5M, Q6M in FIG. 9A and FIG. 9B or in FIG. 10A and FIG. 10B, the sub-gate LB is formed at the lower side of the gate LG, to form a leak type MOS transistor Q5M, Q6M having a special gate structure (for example, refer to Patent Document 4), a so-called F-MONOS (Metal-Oxide-Nitride-Oxide-Semiconductor) structure. Other features are the same as FIG. 9A and FIG. 9B or FIG. 10A and FIG. 10B.

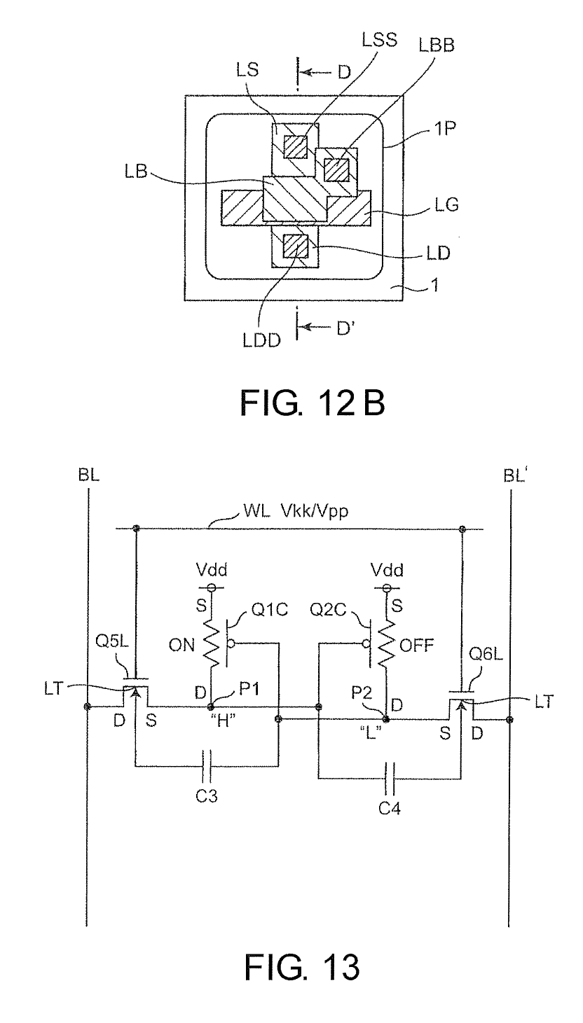

FIG. 12A is a longitudinal sectional-view along the line D-D′ of FIG. 10B illustrating a construction example 4 of an access MOS transistor Q5M, Q6M used in the storage capacitor type SRAM of FIG. 8. FIG. 12B is a top view of the access MOS transistors Q5M, Q6M of FIG. 12A. Comparing the access MOS transistors Q5M, Q6M in FIG. 12A and FIG. 12B with the access MOS transistors Q5M, Q6M in FIG. 9A and FIG. 9B or in FIG. 10A and FIG. 10B, the sub-gate LB is formed extending such that the width is narrowed from the upper side of the gate LG into the gate LG, to form a leak type MOS transistor Q5M, Q6M having a special gate structure (for example, refer to Patent Document 8), a structure used in a so-called hyper SRAM. Other features are the same as FIG. 9A and FIG. 9B or FIG. 10A and FIG. 10B.

In the storage capacitor type SRAM related to the embodiment 4 constructed above, for example, when the MOS transistors Q1T is on and the MOS transistors Q2T is off, the high level voltage of the node P1 may be applied to the sub-gate LB of the access MOS transistor Q6M, and the low level voltage of the node P2 may be applied to the sub-gate LB of the access MOS transistor Q5M, and the bit line BL is retained at the ground voltage during stand-by. In addition, the access MOS transistors Q5M, Q6M include MONOS structures (FIG. 9A˜FIG. 10B), or special gate structures having the sub-gate LB extending from the upper side of the gate LG into the gate LG (FIG. 11A and FIG. 11B). In this way, the access MOS transistors Q5M, Q6M have a leak function, and the leak function is determined by the memory level retained by the nodes P1, P2 of the latch. Therefore, compared to conventional art, a storage capacitor type SRAM having high data retaining ability and a significantly smaller memory size may be achieved.

### Embodiment 5

FIG. 13 is a circuit diagram illustrating a construction example of a storage capacitor type SRAM relating to an embodiment 5 of the invention. Comparing the storage capacitor type SRAM relating to embodiment 5 in FIG. 13 with the storage capacitor type SRAM relating to embodiment 3 in FIG. 6, the differences are as described below.

(1) An integrally formed capacitor TFT type MOS transistors Q1C which has the TFT type MOS transistor Q1T and the capacitor C1 integrally formed is included in place of the TFT type MOS transistors Q1T. Here, the capacitor which is integrally formed with the TFT type MOS transistor Q1C corresponds to the above mentioned capacitor C1.

(2) The integrally formed capacitor TFT type MOS transistors Q2C which has the TFT type MOS transistor Q2T and the capacitor C2 integrally formed is included in place of the TFT type MOS transistors Q2T. Here, the capacitor which is integrally formed with the TFT type MOS transistor Q2C corresponds to the above mentioned capacitor C2.

Furthermore, the access MOS transistors Q5L, Q6L includes an SOI structure and includes the back gate control terminal LT.

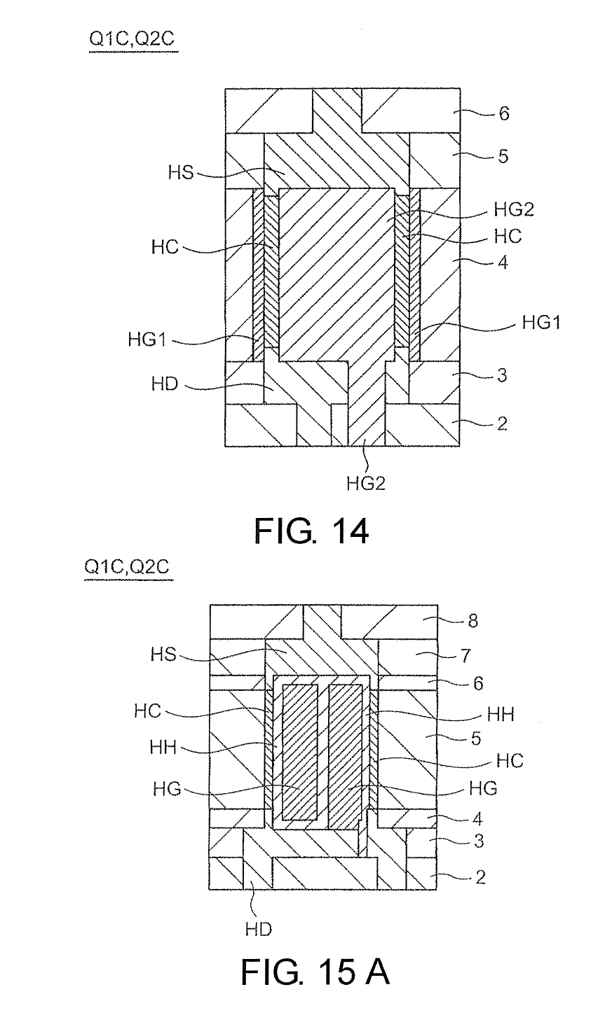

FIG. 14 is a longitudinal sectional-view illustrating a construction example 1 of a TFT type MOS transistor Q1C, Q2C having a large capacity capacitor adapted for the storage capacitor type SRAM of FIG. 13. It should be noted, FIG. 14 is a schematic, and the semiconductor substrate 1 of the lower side of the insulation film 2 and such are omitted from illustration. In the layers of the insulation films 2, 3 of FIG. 14, a drain HD formed from a semiconductor material having the P+ impurity region is formed. The layer of insulation film 4 includes,

(1) a gate HG1 formed from a conductive film,
(2) a channel region HC formed from a particular semiconductor material,
(3) a gate HG2 having a particular width and formed from a conductive film,
(4) a channel region HC formed from the above mentioned semiconductor material,
(5) a gate HG1 formed from a conductive film,
formed juxtaposed. Here, the channel region HC is sandwiched between the source HS and the drain HD so as to form the vertical type TFT type MOS transistor Q1C, Q2C and integrally form the above mentioned capacitor.

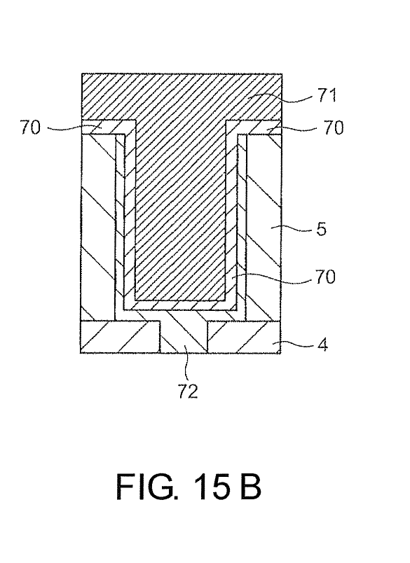

FIG. 15A is a longitudinal sectional-view illustrating a construction example 2 of a TFT type MOS transistor Q1C, Q2C having a large capacity capacitor adapted for the storage capacitor type SRAM of FIG. 13. FIG. 15B is a longitudinal sectional-view illustrating a basic construction of the TFT type MOS transistors Q1C, Q2C having a large capacitance capacitor of FIG. 15A. It should be noted, FIG. 15A and FIG. 15B are schematics, and the semiconductor substrate 1 of the lower side of the insulation film 2 and such are omitted from illustration in FIG. 15A. In the basic construction of FIG. 15B, a high capacitance capacitor may be formed by sandwiching a high dielectric film 70 having a fold back shape in the vertical direction between a conductive film 72 disposed on the outside thereof and a conductive film 71 disposed on the inside thereof.

In the layers of the insulation films 2, 3 of FIG. 15A, a drain HD is formed. In addition, the channel region HC, the high dielectric region HH, the gate region HG, the high dielectric region HH, the gate region HG, the channel region HC are formed juxtaposed in the layers of the insulation film 4, 5. Here, a high capacitance capacitor may be achieved by sandwiching the high dielectric region HH between the channel region HC and the gate region HG. Furthermore, in the layers of the insulation films 7, 8, a source region HS is formed. The vertical type TFT type MOS transistors Q1C, Q2C are formed by sandwiching the channel region HC of the horizontal side of the gate region HG between the source region HS and the drain HD and integrally the above mentioned high capacitance capacitor. Here, the capacitance of the capacitor may be increased by increasing the length of the channel region HC in the vertical direction.

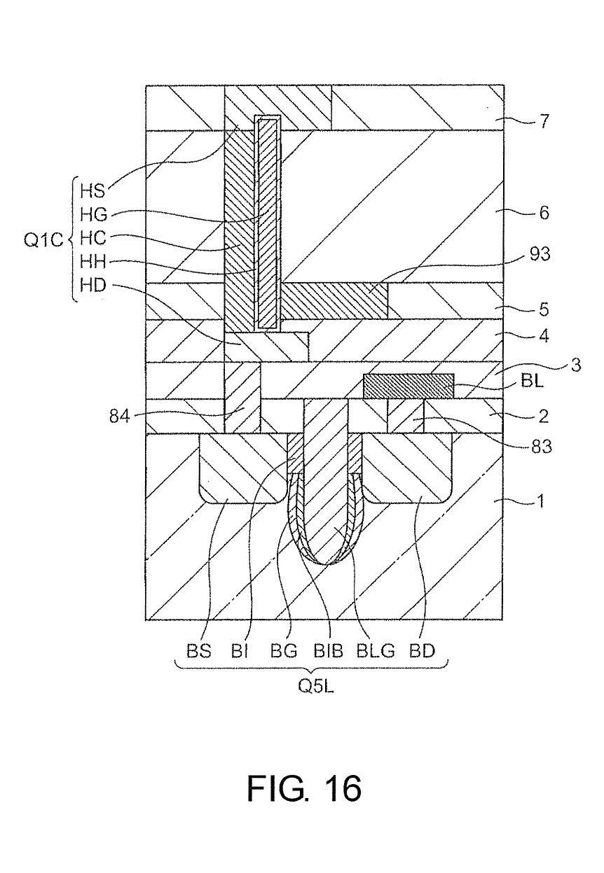

FIG. 16 is a longitudinal sectional-view illustrating a construction example 1 of a part of the storage capacitor type SRAM of FIG. 13. The semiconductor substrate 1 of FIG. 16 includes a source region BS, a gate region BG and a drain region BD so as to form an buried gate type MOS transistor Q5L having a leak function. Here, the gate BG is formed directly below the insulation film BI directly below the main surface of the semiconductor substrate 1 and the leak gate BLG is formed so as to penetrate a central part of the insulation film BI and the gate BG in a thickness direction from the upper side of the main surface of the semiconductor substrate 1, and through for example, an insulation film BIB such as ONO. The drain region BD is connected to the bit line BL through the conductive via 83. The source region BS is connected to the drain region HD of the TFT type MOS transistor Q1C through the conductive via 84. Furthermore, the vertical type integrally formed capacitor TFT type P-channel MOS transistors Q1C having the structure of FIG. 14 or FIG. 15A is similarly formed in the layers of insulation films 4˜7. In addition, the buried gate type MOS transistor Q6L having a leak function is foil red similarly as the MOS transistor Q5L of FIG. 16. Furthermore, the vertical type integrally formed capacitor TFT type P-channel MOS transistors Q2C having the structure of FIG. 14 or FIG. 15A is formed similarly as the MOS transistor Q1C of FIG. 16.

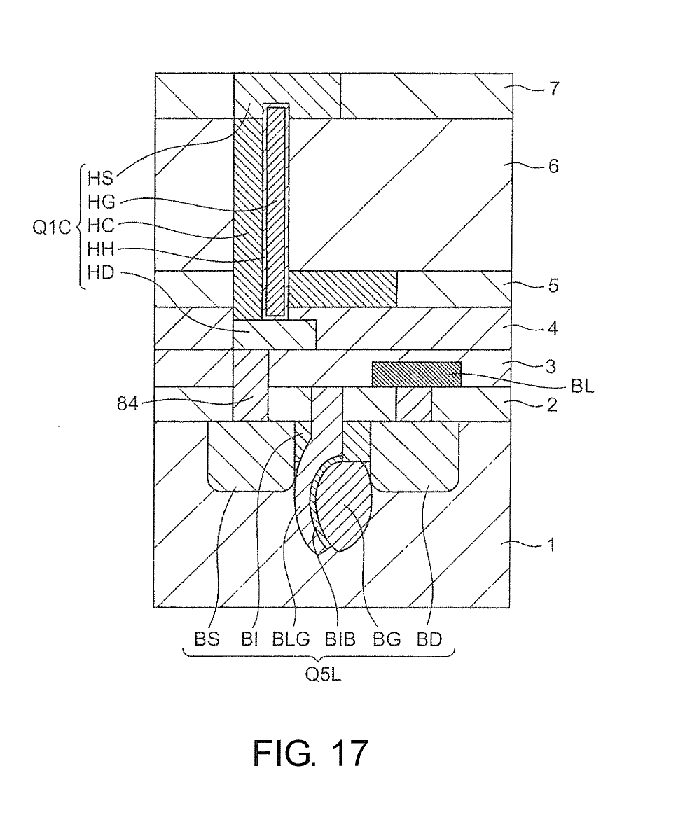

FIG. 17 is a longitudinal sectional-view illustrating a construction example 2 of a part of the storage capacitor type SRAM of FIG. 13. Comparing the structure of FIG. 17 with the structure of FIG. 16, only the leak gate BLG structure of the buried gate type MOS transistor Q5L having a leak function is different. In FIG. 17, the leak gate BLG is formed so as to extend from the upper side of the main surface of the semiconductor substrate 1 along a side surface of the insulation film BI and the gate BG in a thickness direction, and through for example, an insulation film BIB such as ONO. In addition, the buried gate type MOS transistor Q6L having a leak function is similarly formed.

In the storage capacitor type SRAM related to the embodiment 5 constructed above, for example, when the MOS transistor Q1C is on and the MOS transistor Q2C is off, the high level voltage of the node P1 may be applied to the back gate control terminal LT of the access MOS transistor Q6L having the SOI structure, and the low level voltage of the node P2 may be applied to the sub-gate LB of the access MOS transistor Q5L having the SOI structure, and the bit line BL retained at the ground voltage during stand-by. Here, the MOS transistors Q1C, Q2C are vertical type integrally formed capacitor TFT type MOS transistors, and compared to conventional art, a storage capacitor type SRAM having high data retaining ability and a significantly smaller memory size may be achieved.

### Embodiment 6

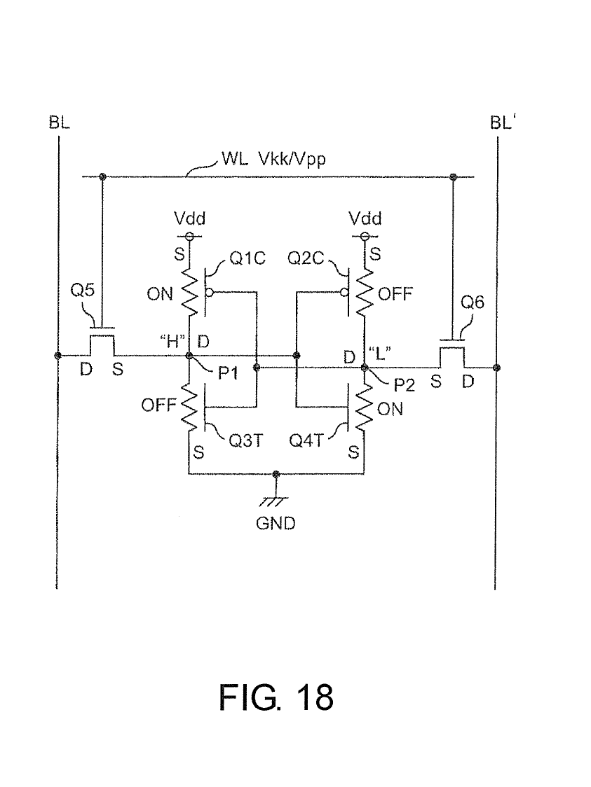

FIG. 18 is a circuit diagram illustrating a construction example of a storage capacitor type SRAM relating to an embodiment 6 of the invention. Comparing the storage capacitor type SRAM relating to embodiment 6 in FIG. 18 with the storage capacitor type SRAM relating to embodiment 2 in FIG. 4, the differences are as described below.

(1) The vertical type integrally formed capacitor TFT type MOS transistor Q1C relating to embodiment 5 is included in place of the MOS transistor Q1T and the capacitor C1.

(2) The vertical type integrally formed capacitor TFT type MOS transistor Q2C relating to embodiment 5 is included in place of the MOS transistor Q2T and the capacitor C2.

The storage capacitor type SRAM constructed above, is formed by the 2 bulk access MOS transistors Q5, Q6 and the latch is formed by the vertical type integrally formed capacitor TFT type MOS transistors Q1C, Q2C. In this way, compared to conventional art, a storage capacitor type SRAM having high data retaining ability and a significantly smaller memory size may be achieved.

### Embodiment 7

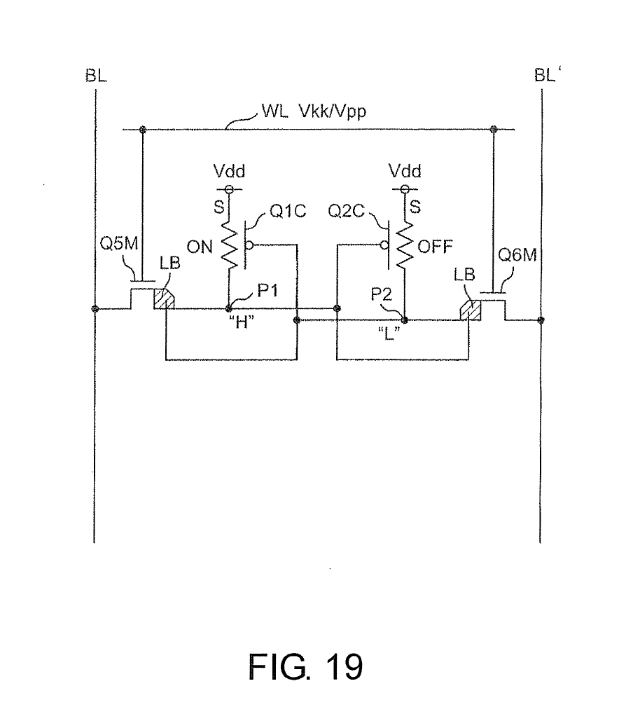

FIG. 19 is a circuit diagram illustrating a construction example of a storage capacitor type SRAM relating to an embodiment 7 of the invention. Comparing the storage capacitor type SRAM relating to embodiment 7 in FIG. 19 with the storage capacitor type SRAM relating to embodiment 4 in FIG. 8, the differences are as described below.
(1) The vertical type integrally formed capacitor TFT type MOS transistor Q1C relating to embodiment 5 is included in place of the MOS transistor Q1T, Q3T and the capacitor C1.

(2) The vertical type integrally formed capacitor TFT type MOS transistor Q2C relating to embodiment 5 is included in place of the MOS transistor Q2T, Q4T and the capacitor C2.

The storage capacitor type SRAM constructed above, is formed by the 2 bulk access MOS transistors Q5M, Q6M respectively having a leak function of the sub-gate LB and the latch is formed by the vertical type integrally formed capacitor TFT type MOS transistors Q1C, Q2C. When the MOS transistors Q1C is on and the MOS transistors Q2C is off, the high level voltage of the node P1 may be applied to the sub-gate LB of the access MOS transistor Q6 having a leak function, and the low level voltage of the node P2 may be applied to the sub-gate LB of the access MOS transistor Q5 having a leak function, and the bit line BL is retained at the ground voltage during stand-by. In this way, compared to conventional art, a storage capacitor type SRAM having high data retaining ability and a significantly smaller memory size may be achieved.

### Embodiment 8

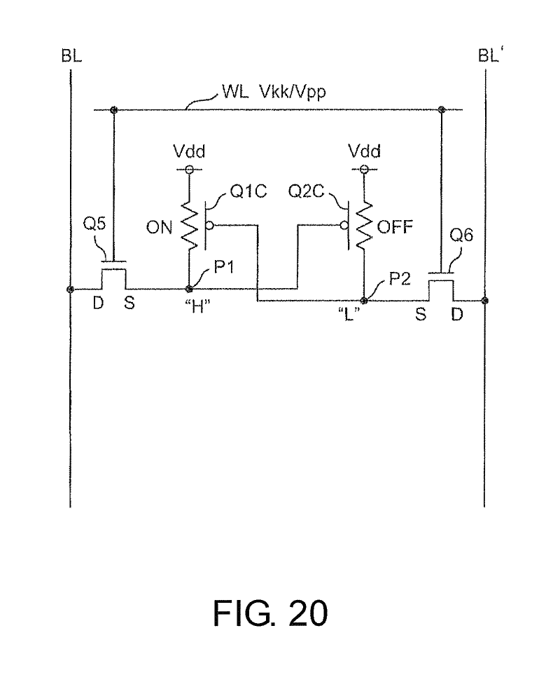

FIG. 20 is a circuit diagram illustrating a construction example of a storage capacitor type SRAM relating to an embodiment 8 of the invention. Comparing the storage capacitor type SRAM relating to embodiment 8 in FIG. 20 with the storage capacitor type SRAM relating to embodiment 2 in FIG. 4, the differences are as described below.

(1) The vertical type integrally formed capacitor TFT type MOS transistor Q1C relating to embodiment 5 is included in place of the MOS transistor Q1T, Q3T and the capacitor C1.

(2) The vertical type integrally formed capacitor TFT type MOS transistor Q2C relating to embodiment 5 is included in place of the MOS transistor Q2T, Q4T and the capacitor C2.

In the present embodiment, compared with embodiments 6 and 7, when the leak current of the access MOS transistor Q5, Q6 is smaller than compared to the TFT type MOS transistors Q1T, Q2T, the MOS transistors having a leak function may be removed and a typical bulk MOS transistor Q5, Q6 may be used.

In the storage capacitor type SRAM constructed above, for example, when the MOS transistors Q1C is on and the MOS transistors Q2C is off, the MOS transistor Q2C sends a relatively small off current; the high level voltage of the node P1 is applied to the source of the access MOS transistor Q6, and the low level voltage of the node P2 is applied to the source of the access MOS transistor Q5, and the bit line BL is retained at the ground voltage during stand-by. In this way, the latch is formed by the vertical type integrally formed capacitor TFT type MOS transistors Q1C, Q2C and the access MOS transistor having a leak function is not used. In this way, compared to conventional art, a storage capacitor type SRAM having high data retaining ability and a significantly smaller memory size may be achieved.

The invention provides a semiconductor memory device having smaller memory size and lower memory cost, and prevents soft errors and latch ups, lowers the stand-by current and achieves a lower low voltage action compared to conventional art.

1. A semiconductor memory device, which is capacitor memory type, comprising:
2 TFT type P-channel MOS transistors and 2 bulk N-channel MOS transistors forming a latch for retaining a data that is inverted between a first node and a second node;
a first bulk access MOS transistor, switching the first node to connect to a first bit line or not according to a voltage of a word line;
a second bulk access MOS transistor, switching the second node to connect to a second bit line or not according to the voltage of the word line;
a first capacitor, disposed between the first node and a particular power supply voltage; and
a second capacitor, disposed between the second node and the power supply voltage,
wherein the 2 bulk N-channel MOS transistors, the first access MOS transistor and the second access MOS transistor are formed by a recess gate type MOS transistor.

2. A semiconductor memory device, which is capacitor memory type, comprising:
2 TFT type P-channel MOS transistors and 2 TFT type N-channel MOS transistors forming a latch for retaining a data that is inverted between a first node and a second node;
a first bulk access MOS transistor, switching the first node to connect to a first bit line or not according to a voltage of a word line;
a second bulk access MOS transistor, switching the second node to connect to a second bit line or not according to the voltage of the word line;
a first capacitor, disposed between the first node and a particular power supply voltage; and
a second capacitor, disposed between the second node and the power supply voltage,
wherein the 4 TFT type MOS transistors are a vertical type TFT type MOS transistor respectively, and include a first P-channel MOS transistor, a second P-channel MOS transistor, a first N-channel MOS transistor and a second N-channel MOS transistor, in which the first P-channel MOS transistor and the first N-channel MOS transistor have a same gate and form a first inverter, and the second P-channel MOS transistor and the second N-channel MOS transistor have a same gate and form a second inverter.

3. A semiconductor memory device, which is capacitor memory type, comprising:
2 TFT type P-channel MOS transistors for retaining a data that is inverted between a first node and a second node;
a first bulk access MOS transistor, switching the first node to connect to a first bit line or not according to a voltage of a word line;
a second bulk access MOS transistor, switching the second node to connect to a second bit line or not according to the voltage of the word line;
a first capacitor, disposed between the first node and a particular power supply voltage; and
a second capacitor, disposed between the second node and the power supply voltage,
wherein the first access MOS transistor and the second access MOS transistor have a leak function, in which the first access MOS transistor is controlled by the leak function according to a voltage of the second node and the second access MOS transistor is controlled by the leak function according to a voltage of the first node.

4. The semiconductor memory device as claimed in claim 3, wherein the first access MOS transistor and the second access MOS transistor have an SOI structure and have a back gate control terminal respectively, and further comprise:
a third capacitor, disposed between the second node and the back gate control terminal of the first access MOS transistor,
a fourth capacitor, disposed between the first node and the back gate control terminal of the second access MOS transistor.

5. The semiconductor memory device as claimed in claim 3, wherein
the first access MOS transistor and the second access MOS transistor have a metal-oxide-nitride-oxide-semiconductor structure or a particular gate structure,
the first access MOS transistor and the second access MOS transistor have a sub-gate respectively,
the second node is connected to the sub-gate of the first access MOS transistor, and
the first node is connected to the sub-gate of the second access MOS transistor.

6. The semiconductor memory device as claimed in claim 1, wherein the first capacitor and the second capacitor are formed by sandwiching a hafnium oxide film or a zirconium oxide film between a pair of metal films.

7. The semiconductor memory device as claimed in claim 2, wherein the first capacitor and the second capacitor are formed by sandwiching a hafnium oxide film or a zirconium oxide film between a pair of metal films.

8. The semiconductor memory device as claimed in claim 3, wherein the first capacitor and the second capacitor are formed by sandwiching a hafnium oxide film or a zirconium oxide film between a pair of metal films.

9. The semiconductor memory device as claimed in claim 4, wherein the first capacitor and the second capacitor are formed by sandwiching a hafnium oxide film or a zirconium oxide film between a pair of metal films.

10. The semiconductor memory device as claimed in claim 5, wherein the first capacitor and the second capacitor are formed by sandwiching a hafnium oxide film or a zirconium oxide film between a pair of metal films.

11. A semiconductor memory device, which is capacitor memory type, comprising:
a first TFT type P-channel MOS transistor and a second TFT type P-channel MOS transistor for retaining a data that is inverted between a first node and a second node;
a first bulk access MOS transistor, switching the first node to connect to a first bit line or not according to a voltage of a word line;
a second bulk access MOS transistor, switching the second node to connect to a second bit line or not according to the voltage of the word line;
wherein the first TFT type P-channel MOS transistor includes a first capacitor integrally formed, disposed between the first node and a particular power supply voltage; and
the second TFT type P-channel MOS transistor includes a second capacitor integrally formed, disposed between the second node and the power supply voltage.

12. The semiconductor memory device as claimed in claim 11, wherein
the first access MOS transistor and second access MOS transistor have a leak function,
the first access MOS transistor is controlled by the leak function according to a voltage of the second node and the second access MOS transistor is controlled by the leak function according to a voltage of the first node.

13. The semiconductor memory device as claimed in claim 12, wherein the first access MOS transistor and second access MOS transistor have an SOI structure and have a back gate control terminal respectively, and further comprise:
a third capacitor, disposed between the second node and the back gate control terminal of the first access MOS transistor,
a fourth capacitor, disposed between the first node and the back gate control terminal of the second access MOS transistor.

14. The semiconductor memory device as claimed in claim 12, wherein
the first access MOS transistor and the second access MOS transistor have a metal-oxide-nitride-oxide-semiconductor structure or a particular gate structure;
the first access MOS transistor and the second access MOS transistor have a sub-gate respectively;
the second node is connected to the sub-gate of the first access MOS transistor; and
the first node is connected to the sub-gate of the second access MOS transistor.
